(19) United States
(12) Patent Application Publication
(10) Pub. No.: US 2016/0007705 A1
(43) Pub. Date: Jan. 14, 2016

(54) Case for a Portable Electronic Device

(71) Applicant: Diversified Products, Inc., Collegeville, PA (US)

(72) Inventors: Steven B. Liebers, Collegeville, PA (US); Zhongqiu Zhu, Wenzhou (CN)

(21) Appl. No.: 14/492,350

(22) Filed: Sep. 22, 2014

Related U.S. Application Data
(63) Continuation-in-part of application No. 14/326,048, filed on Jul. 8, 2014.

(51) Int. Cl. A45C 11/00; H05K 5/03; A45C 11/04

(52) U.S. Cl. CPC A45C 11/00; A45C 11/04; H05K 5/03; A45C 2011/002; A45C 2011/003

(57) ABSTRACT

A case for a portable electronic device is provided, including a primary cover having an outer surface and an inner surface, the inner surface dimensioned to securely retain the portable electronic device, and a pouch to receive a pair of reading glasses on the outer surface of the primary cover. The pouch is secured to the outer surface by a receiver in the form of a pair of parallel tracks disposed on the outer surface of the primary cover that mates with a pair of corresponding rails disposed on the pouch. The cover has a top edge, a bottom edge, a left edge and a right edge. The parallel tracks are parallel to the top edge and the bottom edge.

### CROSS-REFERENCE TO RELATED APPLICATION

This application is a continuation-in-part application of U.S. patent application Ser. No. 14/326,048, filed Jul. 8, 2014, entitled Case for a Portable Electronic Device.

### BACKGROUND OF THE INVENTION

The present invention is directed to protective cases for portable electronic devices, including phones, smart phones, personal digital, tablets and the like. More particularly, the present invention is directed to protective coverings for mobile electronic devices that are capable of holding and protecting other items as well as the mobile electronic device.

Every day, a very large number of people carry hand-held or otherwise portable electronic devices, such as a mobile phones, smart phones and tablets, (e.g., by Samsung, Inc., Blackberry, Ltd, or Apple, Inc.) or similar devices (hereinafter, generically “portable electronic devices”). When a user is out and about with one's portable electronic device, users must still often carry reading glasses in order for the users to clearly see the content displayed on the device. Moreover, since many or most of these electronic devices as well as reading glasses are somewhat fragile, many users desire to have protective coverings or cases to separately protect these electronic devices and reading glasses.

A number of different types of protective cases and coverings are available and are very well known for both portable electronic devices and for reading glasses. For portable electronic devices, many of these cases and coverings are molded from silicone rubber or plastic, some forming a soft covering or “skin” that hugs the contour of the device. Others are hard shell cases made from plastic.

Protective coverings for personal electronic devices are on the market that additionally incorporate a pocket for receiving items. For example, U.S. Pat. No. 8,047,364 (Longinotti-Buitoni) teaches a protective covering having various embodiments of pockets that are incorporated by various means, for example, gluing or sewing (see, e.g., FIGS. 2B and 3). See also U.S. Design Pat. No. D631,246 (Boettner). Other devices provide a combination phone and eyeglass case, but they are complex and expensive to manufacture. For example, U.S. Patent Pub. No. 2011/0210018 (Friedman et al.) discloses such a combination case. However, there is a need to provide a portable electronic device cover that protects the device as well as a pair of reading glasses that is easily and inexpensively manufactured and that adequately protects both reading glasses and the personal electronic device.

All references cited herein are incorporated herein by reference in their entireties.

### BRIEF SUMMARY OF THE INVENTION

In a first exemplary embodiment of the present invention, a case for a portable electronic device is provided. The case includes a primary cover having an outer surface and an inner surface. The inner surface is dimensioned to securely retain the portable electronic device. A pouch for receiving a pair of reading glasses is disposed on the outer surface of the primary cover. The pouch is secured to the outer surface by a receiver in the form of a pair of parallel tracks disposed on the outer surface of the primary cover that mate with a pair of corresponding rails disposed on the pouch.

In a second exemplary embodiment of the present invention, another case for a portable electronic device is provided. The case includes a primary cover having an outer surface and an inner surface. The inner surface is dimensioned to securely retain the portable electronic device. A pouch is provided to receive a pair of reading glasses on the outer surface of the primary cover. The pouch is secured to the outer surface by a receiver in the form of a pair of parallel tracks disposed on the outer surface of the primary cover that mate with a pair of corresponding rails disposed on the pouch. The cover has a top edge, a bottom edge, a left edge and a right edge. The parallel tracks are parallel to the top edge and the bottom edge.

With respect to both embodiments, the rails may slide into the tracks to secure the pouch to the primary cover. The tracks may have a T-shaped cross-sectional opening and the rails may have a mating T-shaped cross section. The pouch may have a lining of a soft fabric. A belt clip may be disposed on the case adjacent to the pouch. The pouch may be disposed parallel to an edge of the primary cover and away from the edge wherein the case is supported by the edge and the pouch to provide an easel support for the case and portable electronic device. Optionally, both the pouch and the primary cover may be manufactured from a polycarbonate thermoplastic polymer. The pouch and/or the primary cover may have, for example, an animal-skin or other indicia thereon.

### BRIEF DESCRIPTION OF SEVERAL VIEWS OF THE DRAWINGS

The invention will be described in conjunction with the following drawings in which like reference numerals designate like elements and wherein:

FIG. 1 is a rear isometric view of a case for a mobile phone in accordance with an exemplary embodiment of the present invention, the case having a pouch for holding reading glasses;

FIG. 2A is a rear isometric view of the case for a mobile phone of FIG. 1, showing a pouch for holding reading glasses prior to installation on the case;

FIG. 2B is a rear isometric view of the case for a mobile phone of FIG. 1, showing the pouch for holding reading glasses installed on the case;

FIG. 3 is a side view of the case for a mobile phone of FIG. 1, shown in an easel position for viewing the display of the mobile phone in a landscape configuration;

FIG. 4 is a rear view of the case for a mobile phone of FIG. 1, showing optional indicia on the pouch for holding reading glasses;

FIG. 5 is a side view of the case for a mobile phone of FIG. 1, showing an optional belt clip;

FIG. 6 is a rear isometric view of a case for a mobile phone in accordance with another exemplary embodiment of the present invention, the case having a pouch for holding reading glasses;

FIG. 7A is a rear isometric view of the case for a mobile phone of FIG. 1, showing a pouch for holding reading glasses prior to installation on the case;

FIG. 7B is a rear isometric view of the case for a mobile phone of FIG. 1, showing the pouch for holding reading glasses installed on the case;

### DETAILED DESCRIPTION OF THE INVENTION

The invention will be illustrated in more detail with reference to the following embodiments, but it should be understood that the present invention is not deemed to be limited thereto.

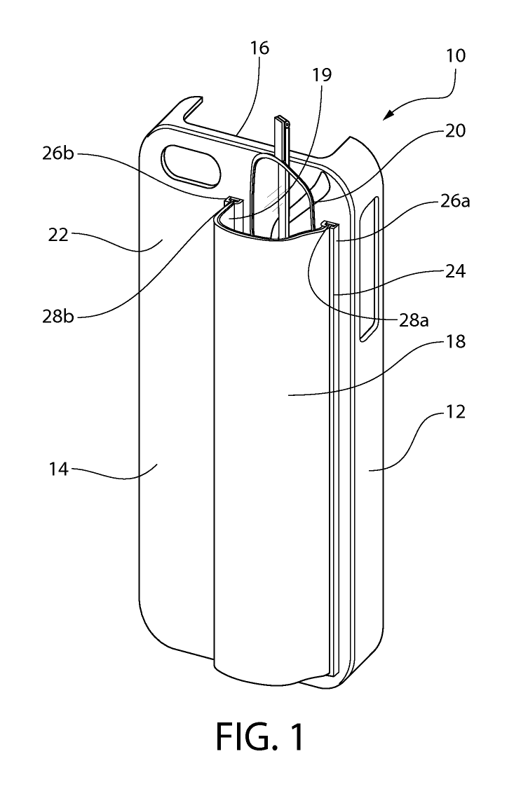

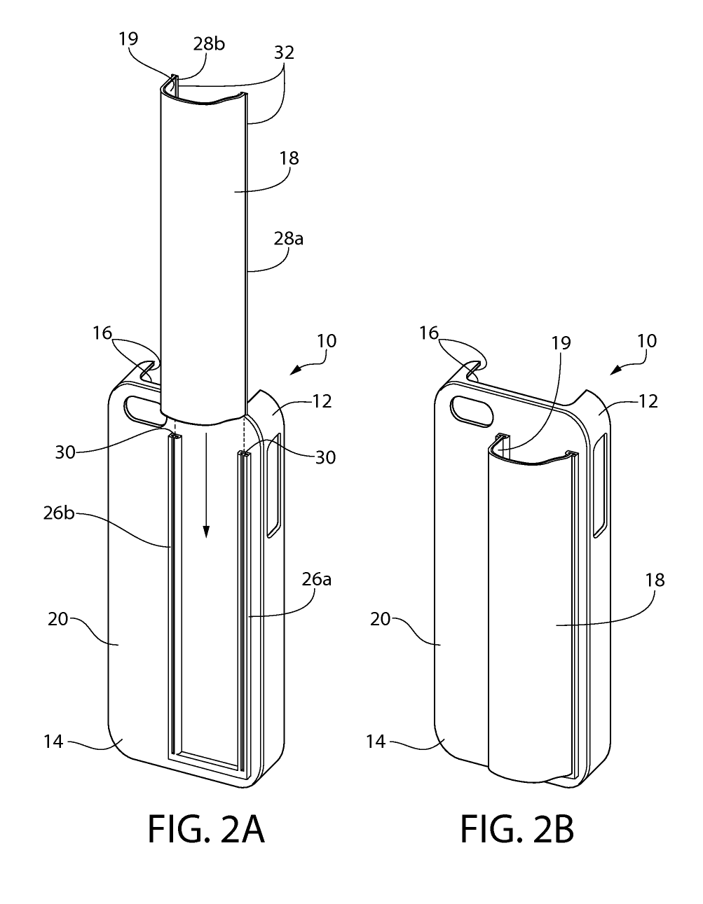

Referring now to the drawing figures, wherein like part numbers refer to like elements throughout the several views, there is shown in FIGS. 1, 2A, 2B a case for a portable electronic device 10 in accordance with an exemplary embodiment of the present invention. The portable electronic device 10 may be, for example, a mobile phone, smart phone (such as an iPhone®), personal digital assistant, electronic tablet (such as an iPad®), and the like. The case 10 includes a primary cover 12 having an outer surface 14 and an inner surface 16. The inner surface 16 is dimensioned to securely retain the portable electronic device 10 by various means well known in the art.

A pouch 18 to receive a pair of reading glasses 20 is disposed on the outer surface 14 (preferably the back surface 22) of the primary cover 12. The pouch 18 is secured to the outer surface 14 by a receiver 24, preferably in the form of a pair of parallel tracks 26a, 26b disposed on the outer surface 14 of the primary cover 12 that mates with a pair of corresponding rails 28a, 28b disposed on the pouch 18. In an exemplary embodiment, the pouch 18 is open where it mates with the outer surface 14 of the primary cover 12 such that the outer surface forms a wall of the pouch 18 for securing the reading glasses 20.

In the exemplary embodiment of the case 10, the parallel rails 28a, 28b of the pouch 18 are slid into the tracks 26a, 26b of the outer surface 14 of the primary cover 12 to secure the pouch 18 to the primary cover 12. The tracks 26a, 26b may have a T-shaped cross-sectional opening 30 that mate with a T-shaped cross section 32 of the rails 28a, 28b to securely hold the pouch 18 on the cover 12. Alternatively the rails 28a, 28b may have a T-shaped cross-sectional opening and the tracks 26a, 26b may have a T-shaped cross section.

In one exemplary embodiment, both the pouch 18 and the primary cover 12 are made from polycarbonate thermoplastic polymer. However, the pouch 18 may have a lining 19 of a soft fabric, such as velvet.

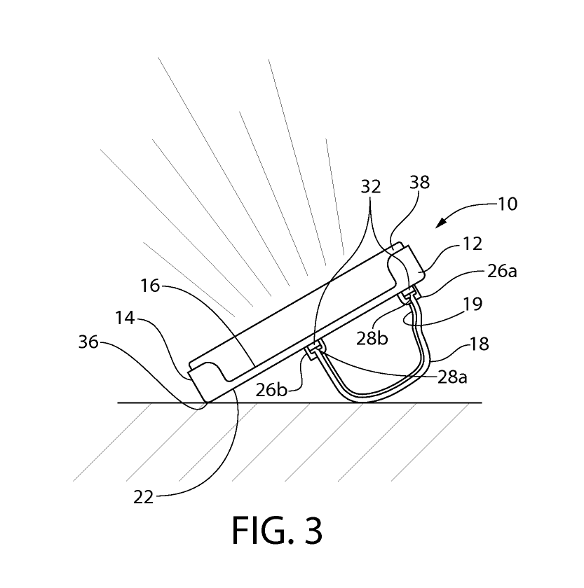

As shown in FIG. 3, the pouch 18 may be disposed on the primary cover 12 parallel to an edge 36 of the primary cover 12 and away from the edge 12 such that the case 10 is supported by the edge 36 and the pouch 18 to provide an easel support for the case 10 and portable electronic device 38.

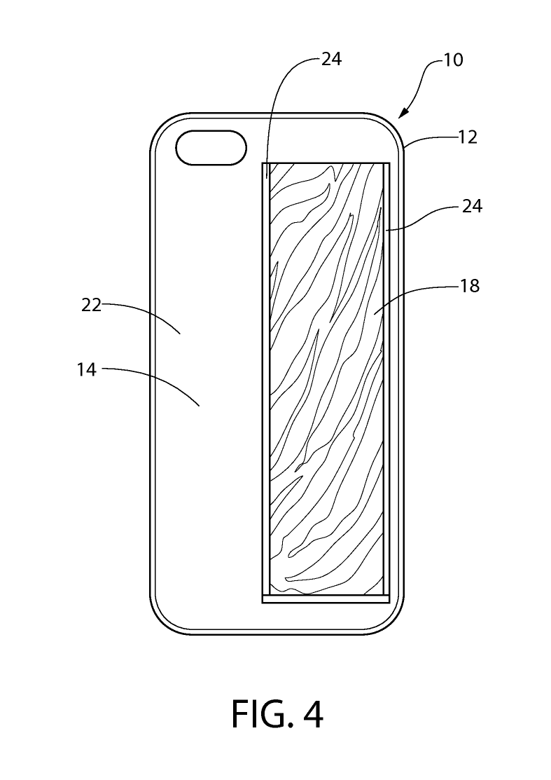

As shown in FIG. 4, the pouch 18 may have animal-skin (or other) indicia thereon. Likewise, the primary cover may have such indicia.

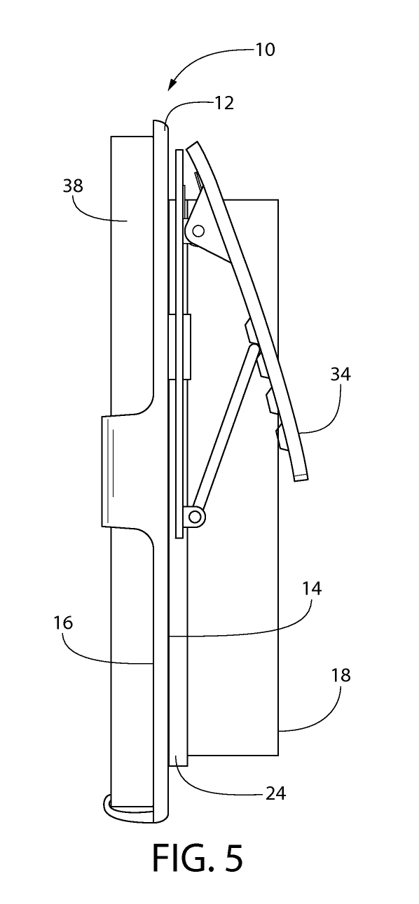

As shown in FIG. 5, a belt clip 34 may be disposed on the case 10 adjacent to the pouch 18, preferably on the back surface 22.

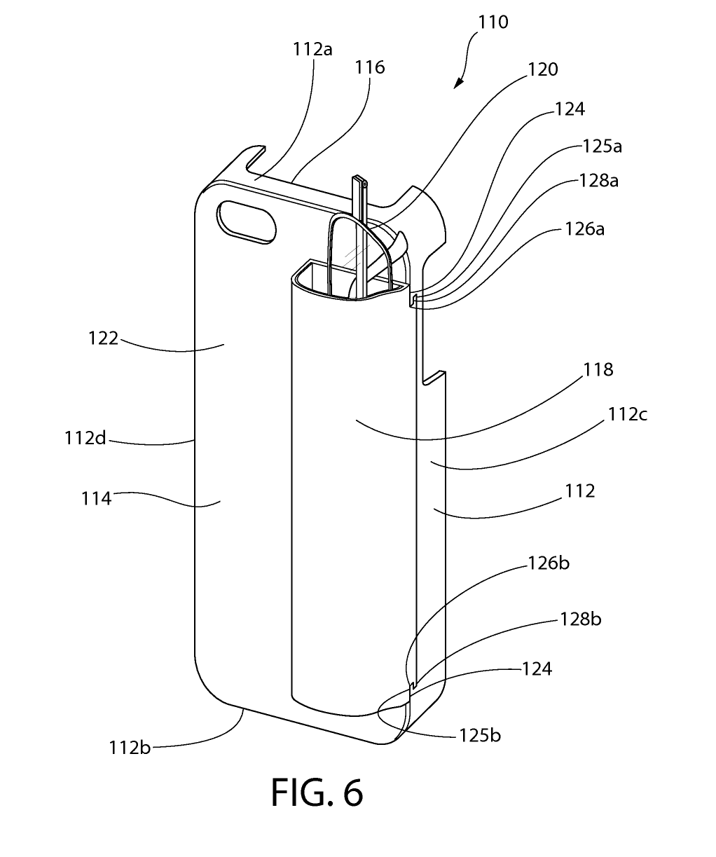

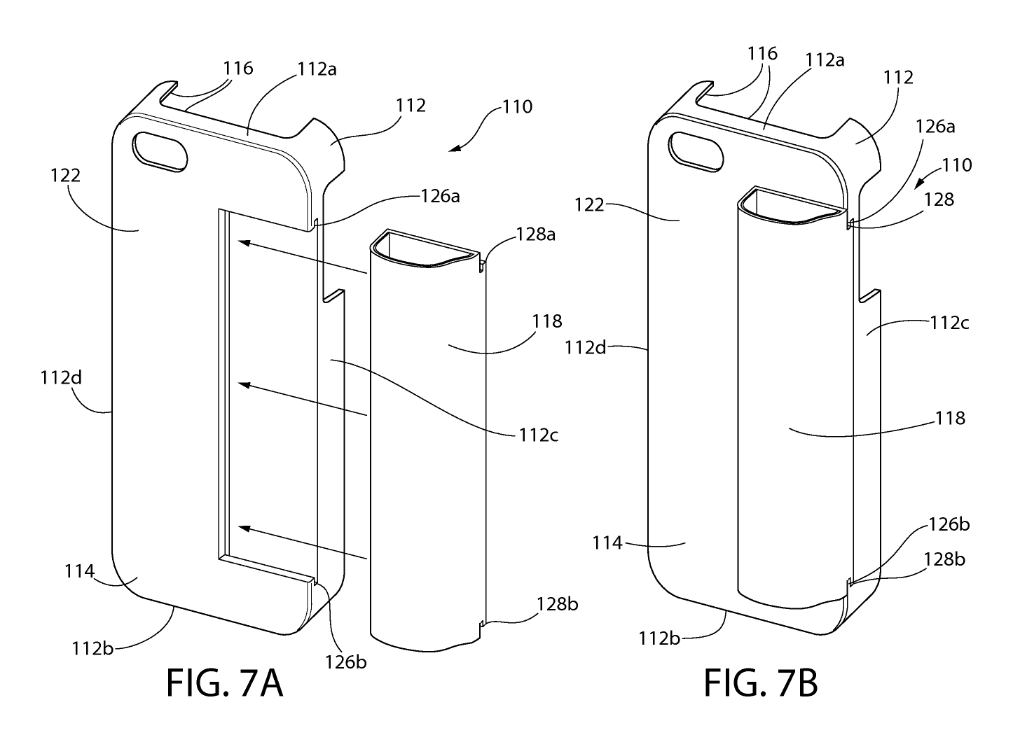

There is shown in FIGS. 6, 7A, 7B a case for a portable electronic device 110 in accordance with another exemplary embodiment of the present invention. The case 110 includes a primary cover 112 having an outer surface 114 and an inner surface 116. The inner surface 116 is dimensioned to securely retain the portable electronic device 110 by one of various means well known in the art.

A pouch 118 to receive a pair of reading glasses 120 is disposed on the outer surface 114 (preferably the back surface 122) of the primary cover 112. The pouch 118 is secured to the outer surface 114 by a receiver 124, preferably in the form of a pair of parallel tracks 126a, 126b disposed on the outer surface 114 of the primary cover 112 that mates with a pair of corresponding rails 128a, 128b disposed on the pouch 118. In an exemplary embodiment, the pouch 118 is open where it mates with the outer surface 114 of the primary cover 112 such that the outer surface forms a wall of the pouch 118 for securing the reading glasses 120.

In the exemplary embodiment of the case 110, the parallel rails 128a, 128b of the pouch 118 are slid into the tracks 126a, 126b of the outer surface 114 of the primary cover 112 to secure the pouch 118 to the primary cover 112. The cover 112 has a top edge 112a, bottom edge 112b, a left edge 112c, and a right edge 112d. In the embodiment of FIG. 6, 7A, and 7B. The parallel tracks 126a, 126b are parallel to the top edge 112a and the bottom edge 112b.

Preferably, a first track 126a of the pair of parallel tracks 126a, 126b is disposed adjacent to and parallel to the top edge 112a. Here, a first rail 128a of the pair of rails 128a, 128b on the pouch 118 has a leg 125a disposed towards the top edge 112a. A second track 126b of the pair of parallel tracks 126a, 126b is disposed adjacent to and parallel to the bottom edge 112b. Here, the second rail 128b of the pair of rails 128a, 128b on the pouch 118 has a leg 125b disposed towards the bottom edge 112b. The pouch 118 slides into position and is held in place by the tracks 126a, 126b mating with the rails 128a, 128b.

While the invention has been described in detail and with reference to specific embodiments, it will be apparent to one skilled in the art that various changes and modifications can be made therein without departing from the spirit and scope thereof.

1. A case for a portable electronic device, comprising:
(a) a primary cover having an outer surface and an inner surface, the inner surface dimensioned to securely retain the portable electronic device; and
(b) a pouch adopted to receive a pair of reading glasses on the outer surface of the primary cover, the pouch secured to the outer surface by a receiver in the form of a pair of parallel tracks disposed on the outer surface of the primary cover that mates with a pair of corresponding rails disposed on the pouch, wherein the cover has a top edge, a bottom edge, a left edge and a right edge, and wherein the parallel tracks are parallel to the top edge and the bottom edge, wherein the rails slide into the tracks to secure the pouch to the primary cover, wherein a first track of the pair of parallel tracks is disposed adjacent to and parallel to the top edge, and wherein a first rail of the pair of rails on the pouch has a leg disposed towards the top edge, and wherein a second track of the pair of parallel tracks is disposed adjacent to and parallel to the bottom edge, and wherein a second rail of the pair of rails on the pouch has a leg disposed towards the bottom edge.

2. (canceled)

3. (canceled)

4. The case for a portable electronic device of claim 1, wherein the pouch has a lining of a soft fabric.

5. The case for a portable electronic device of claim 1, including a belt clip disposed on the case adjacent to the pouch.

6. The case for a portable electronic device of claim 1, wherein the pouch is disposed parallel to one of the right side edge and the left side edge of the primary cover and away from the edge wherein the case is supported by the right side edge or the left side edge and the pouch to provide an easel support for the case and portable electronic device.

7. The case for a portable electronic device of claim 1, wherein both the pouch and the primary cover are polycarbonate thermoplastic polymer.

8. The case for a portable electronic device of claim 1, wherein the pouch has animal-skin indicia thereon.
